(19) United States
(12) Patent Application Publication
(10) Pub. No.: US 2025/0189600 A1
(43) Pub. Date: Jun. 12, 2025

(54) FAULT DIAGNOSIS DEVICE AND FAULT DIAGNOSIS METHOD FOR ELECTRIC VEHICLE CHARGING SYSTEM

(71) Applicants: Hyundai Motor Company, Seoul (KR); Kia Corporation, Seoul (KR)

(72) Inventor: JinSu Jang, Hwaseong-si (KR)

(21) Appl. No.: 18/916,437

(22) Filed: Oct. 15, 2024

(30) Foreign Application Priority Data
Dec. 12, 2023 (KR) 10-2023-0179572

(51) Int. Cl. G01R 31/58

(52) U.S. Cl. CPC G01R 31/58

(57) ABSTRACT

A fault diagnosis device and a fault diagnosis method for an electric vehicle charging system. The fault diagnosis device may include: a first terminal node receiving a control pilot (CP) signal from a connector of a charger through an inlet and connected to an anode of a diode; a first node connected to a cathode of the diode; a second node selectively connected to the first terminal node by a switch; a third node connected to the second node through a first resistor; a second terminal node connected to the third node through a second resistor; and a processor configured to measure a first voltage of the first node, a second voltage of the second node, and a third voltage of the third node to diagnose a fault on the CP line.

### CROSS-REFERENCE TO RELATED APPLICATIONS

This application claims priority to and the benefit of Korean Patent Application No. 10-2023-0179572 filed in the Korean Intellectual Property Office on Dec. 12, 2023, the entire contents of which are incorporated herein by reference.

### TECHNICAL FIELD

The present disclosure relates to a fault diagnosis device and a fault diagnosis method for an electric vehicle charging system.

### BACKGROUND

In line with global trends such as exhaust gas emission regulations for internal combustion engine vehicles and the introduction of eco-friendly vehicles, the production of internal combustion engine vehicles is being reduced and the transition to electric vehicles is taking place. Accordingly, construction of infrastructure for charging electric vehicles is also actively underway. An electric vehicle receives electrical energy from the outside, charges a battery with the electrical energy, and then uses a voltage charged in the battery to obtain power, which is mechanical energy, through a motor connected to wheels. Therefore, it is important to construct a charging infrastructure to charge rechargeable batteries of electric vehicles. While charging an electric vehicle at a charging station, a physical fault in which a control pilot (CP) line is open-circuited or short-circuited may occur. Because a CP signal has a key function in charging control, such as requesting the start or stop of power transmission or controlling the amount of power, a fault diagnosis method for the CP line needs to be prepared. In particular, it is necessary to accurately diagnose whether a fault has occurred in a CP line inside a vehicle or in a CP line on an external charger side.

### SUMMARY

An embodiment of the present disclosure can provide a fault diagnosis device and a fault diagnosis method for an electric vehicle charging system, which can be capable of accurately diagnosing a fault on a control pilot (CP) line used when charging an electric vehicle.

A fault diagnosis device according to an example embodiment may include: a first terminal node receiving a control pilot (CP) signal from a connector of a charger through an inlet and connected to an anode of a diode; a first node connected to a cathode of the diode; a second node selectively connected to the first terminal node by a switch; a third node connected to the second node through a first resistor; a second terminal node connected to the third node through a second resistor; and a processor measuring a first voltage of the first node, a second voltage of the second node, and a third voltage of the third node to diagnose a fault on the CP line.

The second terminal node may be connected to the third node through a third resistor and a fault diagnosis power supply.

The second terminal node may be connected to the first node through a fourth resistor.

The processor may diagnose that the CP line is open-circuited between the charger and the inlet in a case where the first voltage, the second voltage, and the third voltage are measured according to Equation 1-1, Equation 1-2, and Equation 1-3:

$${V}_{1} = \frac{{R}_{11} ( {V}_{3} - {V}_{D} )}{{R}_{11} + {R}_{1}} \qquad Equation 1 - 1$$

$${V}_{2} = \frac{{R}_{11} ( {V}_{3} - {V}_{D} )}{{R}_{11} + {R}_{1}} {V}_{D} \qquad Equation 1 - 2$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad Equation 1 - 3$$

where R₁ represents a first resistance, R₂ represents a second resistance, R₃ represents a third resistance, R₁₁ represents a fourth resistance, V₁ represents the first voltage, V₂ represents the second voltage, V₃ represents the third voltage, V_{Diag} represents a voltage of the fault diagnosis power supply, and V_{D} represents a conduction voltage of the diode.

The processor may diagnose that the connector of the charger is connected to the inlet, and the CP line is open-circuited between the inlet and the first node in a case where the first voltage, the second voltage, and the third voltage are measured according to Equation 2-1, Equation 2-2, and Equation 2-3:

$${V}_{1} = 0 \qquad Equation 2 - 1$$

$${V}_{2} = {V}_{CP} - \frac{{R}_{31} ( {V}_{CP} - {V}_{3} )}{{R}_{1} + {R}_{31}} \qquad Equation 2 - 2$$

$${V}_{3} = \frac{{V}_{CP} {R}_{2} {R}_{3} + {V}_{Diag} ( {R}_{1} + {R}_{31} ) {R}_{2}}{( {R}_{1} + {R}_{31} ) {R}_{2} + ( {R}_{1} + {R}_{31} ) {R}_{3} + {R}_{2} {R}_{3}} \qquad Equation 2 - 3$$

where, R₁ represents a first resistance, R₂ represents a second resistance, R₃ represents a third resistance, V₁ represents the first voltage, V₂ represents the second voltage, V₃ represents the third voltage, V_{Diag} represent a voltage of the fault diagnosis power supply, V_{CP} represents a CP voltage provided by the charger, and R₃₁ represents a resistance of a resistor connected to an output terminal of a CP pulse width modulation (PWM) generation circuit in the charger.

The processor may diagnose that the connector of the charger is not connected to the inlet, and the CP line is open-circuited between the inlet and the first node in a case where the first voltage, the second voltage, and the third voltage are measured according to Equation 3-1, Equation 3-2, and Equation 3-3:

$${V}_{1} = 0 \qquad Equation 3 - 1$$

$${V}_{2} = {V}_{3} \qquad Equation 3 - 2$$

$${V}_{3} = {V}_{Diag} \frac{{R}_{2}}{{R}_{2} + {R}_{3}} \qquad Equation 3 - 3$$

where R₂ represents a second resistance, R₃ represents a third resistance, V₁ represents the first voltage, V₂ represents the second voltage, V₃ represents the third voltage, and V_{Diag} represents a voltage of the fault diagnosis power supply.

The processor may diagnose that the connector of the charger is connected to the inlet, and the CP line is short-circuited between the charger and the inlet in a case where the first voltage, the second voltage, and the third voltage are measured according to Equation 4-1, Equation 4-2, and Equation 4-3:

$${V}_{1} = {V}_{EVSE} - {V}_{D} \qquad Equation 4 - 1$$

$${V}_{2} = {V}_{EVSE} \qquad Equation 4 - 2$$

$${V}_{3} = \frac{{V}_{EVSE} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad Equation 4 - 3$$

where R₁ represents a first resistance, R₂ represents a second resistance, R₃ represents a third resistance, V₁ represents the first voltage, V₂ represents the second voltage, V₃ represents the third voltage, V_{Diag} represents a voltage of the fault diagnosis power supply, and V_{EVSE} represents a charger power supply voltage.

The processor may diagnose that the connector of the charger is not connected to the inlet, and the CP line is short-circuited to a charger power supply voltage between the charger and the inlet in a case where the first voltage, the second voltage, and the third voltage are measured according to Equation 5-1, Equation 5-2, and Equation 5-3:

$${V}_{1} = \frac{{R}_{11} ( {V}_{3} - {V}_{D} )}{{R}_{11} + {R}_{1}} \qquad Equation 5 - 1$$

$${V}_{2} = \frac{{R}_{11} ( {V}_{3} - {V}_{D} )}{{R}_{11} + {R}_{1}} + {V}_{D} \qquad Equation 5 - 2$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad Equation 5 - 3$$

where R₁ represents a first resistance, R₂ represents a second resistance, R₃ represents a third resistance, R₁₁ represents a fourth resistance, V₁ represents the first voltage, V₂ represents the second voltage, V₃ represents the third voltage, V_{Diag} represents a voltage of the fault diagnosis power supply, and V_{D} represents a conduction voltage of the diode.

The processor may diagnose that the CP line is short-circuited to a vehicle power supply voltage between the inlet and the first node in a case where the first voltage, the second voltage, and the third voltage are measured according to Equation 6-1, Equation 6-2, and Equation 6-3:

$${V}_{1} = {V}_{B +} - {V}_{D} \qquad Equation 6 - 1$$

$${V}_{2} = {V}_{B +} \qquad Equation 6 - 2$$

$${V}_{3} = \frac{{V}_{B +} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad Equation 6 - 3$$

where R₁ represents a first resistance, R₂ represents a second resistance, R₃ represents a third resistance, V₁ represents the first voltage, V₂ represents the second voltage, V₃ represents the third voltage, V_{Diag} represents a voltage of the fault diagnosis power supply, V_{B+} represents the vehicle power supply voltage, and V_{D} represents a conduction voltage of the diode.

The processor may diagnose that the connector of the charger is connected to the inlet, and the CP line is short-circuited to a ground between the charger and the inlet in a case where the first voltage, the second voltage, and the third voltage are measured according to Equation 7-1, Equation 7-2, and Equation 7-3:

$${V}_{1} = 0 \qquad Equation 7 - 1$$

$${V}_{2} = 0 \qquad Equation 7 - 2$$

$${V}_{3} = \frac{{V}_{Diag} {R}_{1} {R}_{2}}{{R}_{1} {R}_{2} + {R}_{1} {R}_{3} + {R}_{2} {R}_{3}} \qquad Equation 7 - 3$$

where R₁ represents a first resistance, R₂ represents a second resistance, R₃ represents a third resistance, V₁ represents the first voltage, V₂ represents the second voltage, V₃ represents the third voltage, and V_{Diag} represents a voltage of the fault diagnosis power supply.

The processor may diagnose that the connector of the charger is not connected to the inlet, and the CP line is short-circuited to a ground between the charger and the inlet in a case where the first voltage, the second voltage, and the third voltage are measured according to Equation 8-1, Equation 8-2, and Equation 8-3:

$${V}_{1} = \frac{{R}_{11} ( {V}_{3} - {V}_{D} )}{{R}_{11} + {R}_{1}} \qquad Equation 8 - 1$$

$${V}_{2} = \frac{{R}_{11} ( {V}_{3} - {V}_{D} )}{{R}_{11} + {R}_{1}} + {V}_{D} \qquad Equation 8 - 2$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad Equation 8 - 3$$

where R₁ represents a first resistance, R₂ represents a second resistance, R₃ represents a third resistance, R₁₁ represents a fourth resistance, V₁ represents the first voltage, V₂ represents the second voltage, V₃ represents the third voltage, V_{Diag} represents a voltage of the fault diagnosis power supply, and V_{D} represents a conduction voltage of the diode.

The processor may diagnose that the CP line is short-circuited to a ground between the inlet and the first node in a case where the first voltage, the second voltage, and the third voltage are measured according to Equation 9-1, Equation 9-2, and Equation 9-3:

$${V}_{1} = 0 \qquad Equation 9 - 1$$

$${V}_{2} = 0 \qquad Equation 9 - 2$$

$${V}_{3} = \frac{{V}_{Diag} {R}_{1} {R}_{2}}{{R}_{1} {R}_{2} + {R}_{1} {R}_{3} + {R}_{2} {R}_{3}} \qquad Equation 9 - 3$$

where R₁ represents a first resistance, R₂ represents a second resistance, R₃ represents a third resistance, V₁ represents the first voltage, V₂ represents the second voltage, V₃ represents the third voltage, and V_{Diag} represents a voltage of the fault diagnosis power supply.

The processor may diagnose that an internal fault of the charger has occurred in a case where the first voltage, the second voltage, and the third voltage are measured according to Equation 10-1, Equation 10-2, and Equation 10-3:

$${V}_{1} = 0 \qquad Equation 10 - 1$$

$${V}_{2} = {V}_{CP} - \frac{{R}_{31} ( {V}_{CP} - {V}_{3} )}{{R}_{1} + {R}_{31}} \qquad Equation 10 - 2$$

$${V}_{3} = \frac{{V}_{CP} {R}_{2} {R}_{3} + {V}_{Diag} ( {R}_{1} + {R}_{31} ) {R}_{2}}{( {R}_{1} + {R}_{31} ) {R}_{2} + ( {R}_{1} + {R}_{31} ) {R}_{3} + {R}_{2} {R}_{3}} \qquad Equation 10 - 3$$

where, R₁ represents a first resistance, R₂ represents a second resistance, R₃ represents a third resistance, V₁ represents the first voltage, V₂ represents the second voltage, V₃ represents the third voltage, V_{Diag} represent a voltage of the fault diagnosis power supply, V_{CP} represents a CP voltage provided by the charger, and R₃₁ represents a resistance of a resistor connected to an output terminal of a CP PWM generation circuit in the charger.

A fault diagnosis method according to an example embodiment may include: turning on a switch; measuring a first voltage of a first node connected to a cathode of a diode receiving a control pilot (CP) signal from a connector of a charger through an inlet; measuring a second voltage of a second node selectively connected to a first terminal node connected to an anode of the diode by the switch; measuring a third voltage of a third node connected to the second node through a first resistor; loading data in which result values calculated from predetermined equations for each fault type are stored into a memory; and diagnosing a fault on a CP line by comparing the calculated result values and result values of the measured first voltage, second voltage, and third voltage.

The turning on of the switch may include terminating charging and turning on the switch in a case where the first voltage is recognized as being in a predetermined range during vehicle charging.

A fault diagnosis method may further include: identifying the fault type in a case where the connector of the charger is connected to the inlet; identifying the fault type in a case where the connector of the charger is not connected to the inlet; and confirming a final fault type by comparing the fault type identified in a case where the charger is connected to the inlet and the fault type identified in a case where the charger is not connected to the inlet.

### BRIEF DESCRIPTION OF THE DRAWINGS

FIG. 1 is a schematic diagram illustrating a fault diagnosis device for an electric vehicle charging system according to an example embodiment of the present disclosure;

FIG. 2 is a flowchart diagram illustrating a fault diagnosis method for an electric vehicle charging system according to an example embodiment of the present disclosure;

FIGS. 3 and 4 are diagrams, each illustrating a fault diagnosis device when no fault occurs according to an example embodiment of the present disclosure; and

FIGS. 5 to 17 are diagrams, each illustrating a fault diagnosis device when a fault occurs according to an example embodiment of the present disclosure.

### DETAILED DESCRIPTION OF ILLUSTRATIVE EMBODIMENTS

Hereinafter, example embodiments of the present disclosure will be described more fully with reference to the accompanying drawings so as to be easily practiced by those skilled in the art to which the present disclosure pertains. As those skilled in the art can realize, the described example embodiments may be modified in various different ways, all without departing from the spirit or scopes of the present disclosure. Accordingly, the drawings and description can be regarded as illustrative in nature and not necessarily restrictive. Like reference numerals can designate like elements throughout the present specification.

Throughout the present specification and the claims, unless explicitly described to the contrary, the word “comprise” and variations such as “comprises” or “comprising”, can be understood to imply the inclusion of stated elements but not the exclusion of any other elements. Terms including an ordinal number such as “first” and “second” may be used to describe various components, but these components are not necessarily limited by these terms. These terms can be used merely for the purpose of distinguishing one component from another component.

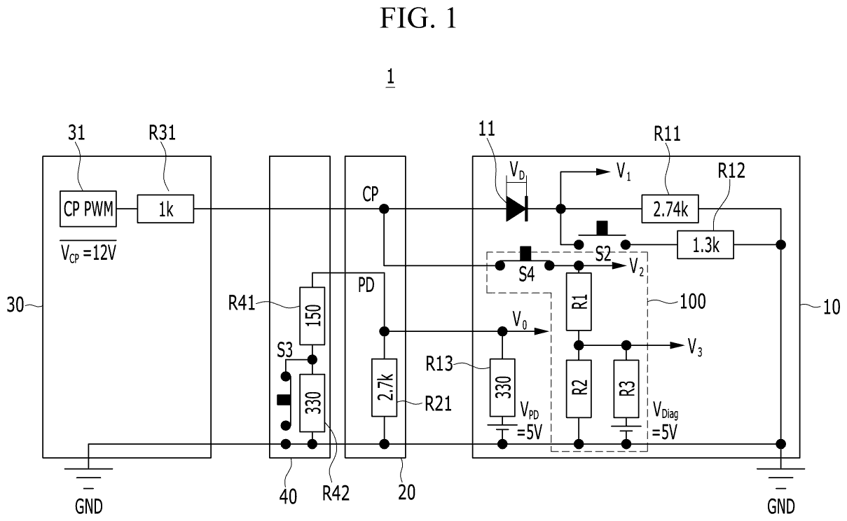

FIG. 1 is a diagram illustrating a fault diagnosis device for an electric vehicle charging system according to an example embodiment.

Referring to FIG. 1, an electric vehicle charging system 1 according to an example embodiment may include a vehicle 10, an inlet 20, a charger 30, and a connector 40.

The vehicle 10 may be an eco-friendly vehicle that uses battery charging, such as an electric vehicle (EV) or a plug-in hybrid electric vehicle (PHEV). The charger 30 may be electric vehicle supply equipment installed at a charging station to charge batteries of eco-friendly vehicles. The inlet 20 may be provided in the vehicle 10 and may be connected to the connector 40 of the charger 30 to receive power from the charger 30. Further, the inlet 20 may receive various information regarding the charger 30, such as cable information, a charging method, a rated voltage, a charging time, voltage information, and current information, for example.

The vehicle 10 may include a first terminal node, a diode 11, a first node, a switch S2, and resistors R11 and R12. The first terminal node corresponding to an anode of the diode 11 may receive a control pilot (CP) signal from the connector 40 of the charger 30 through the inlet 20. The first node corresponding to a cathode of the diode 11 may be, on the one hand, connected to a ground terminal GND through the resistor R11, and on the other hand, connected to the ground terminal GND through the switch S2 and the resistor R12. The vehicle 10 may further include a second terminal node corresponding to the ground terminal GND. A first voltage V₁ of the first node may be a voltage measured for fault diagnosis.

The vehicle 10 may further include a fault diagnosis device 100. The fault diagnosis device 100 may include a switch S4, a second node, a third node, and resistors R1, R2, and R3. The switch S4 may be used to operate the fault diagnosis device 100, one end of the switch S4 may be connected to the first terminal node, and the other end of the switch S4 may be connected to the second node. That is, the second node may be selectively connected to the first terminal node by the switch S4. One end of the resistor R1 may be connected to the second node, and the other end of the resistor R1 may be connected to the third node. That is, the third node may be connected to the second node through the resistor R1. One end of the resistor R2 may be connected to the third node, and the other end of the resistor R2 may be connected to the second terminal node. That is, the second terminal node may be connected to the third node through the resistor R2. The second terminal node may be connected to the third node through the resistor R3 and a fault diagnosis power supply V_{Diag}. The second terminal node may also be connected to the first node through the resistor R11. A second voltage V₂ of the second node and a third voltage V₃ of the third node may be voltages measured for fault diagnosis.

The charger 30 may include a CP pulse width modulation (PWM) generation circuit 31 and a resistor R31. The CP PWM generation circuit 31 may output the CP signal in a pulse width modulation form. The interior of the inlet 20 and the connector 40 may be intuitively referred to in FIG. 1.

In a case where the first voltage V₁ is recognized as being 0 V or exceeding 9.56 V while charging the vehicle 10, the vehicle 10 may primarily recognize that a CP line has failed and stop charging. Then, the vehicle 10 may turn on the switch S4 to drive the fault diagnosis device 100 and measure the first voltage V₁, the second voltage V₂, and the third voltage V₃, thereby primarily diagnosing the fault on the CP line. Thereafter, after a user removes the connector 40 and starts the vehicle 10, the vehicle 10 may turn on the switch S4 again to drive the fault diagnosis device 100 and measure the first voltage V₁, the second voltage V₂, and the third voltage V₃, thereby secondarily diagnosing the fault on the CP line. It can be possible to determine whether the fault has occurred in a portion of the CP line inside the vehicle 10 or in a portion of the CP line outside the vehicle 10, and determine a final fault type accordingly by combining results of the primary diagnosis and the secondary diagnosis.

Values of the resistors R1, R2, and R3 may be set to large values that do not affect a tolerance voltage range for each basic charging state even when the switch S4 is turned on in a normal state.

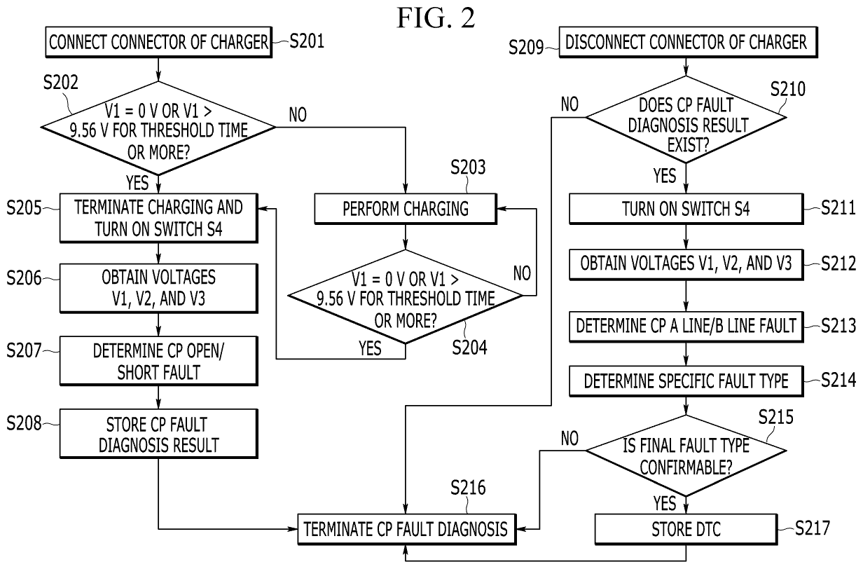

FIG. 2 is a flowchart diagram illustrating a fault diagnosis method for an electric vehicle charging system according to an example embodiment.

Referring to FIG. 2, a fault diagnosis method for an electric vehicle charging system according to an example embodiment may perform an operation of connecting a charging connector (operation S201) and an operation of determining whether the first voltage V₁ is recognized as being 0 V or exceeding 9.56 V for a threshold time or more (operation S202). In a case where it is determined that the first voltage V₁ is not recognized as being 0 V or exceeding 9.56 V for the threshold time or more, the method may perform an operation of performing charging (operation S203) and an operation of determining whether the first voltage V₁ is recognized as being 0 V or exceeding 9.56 V for the threshold time or more (operation S204).

In a case where it is determined that the first voltage V₁ is recognized as being 0 V or exceeding 9.56 V for the threshold time or more, the method may perform an operation of terminating charging and turning on the switch S4 (operation S205), an operation of obtaining the first voltage V₁, the second voltage V₂, and the third voltage V₃ (operation S206), an operation of determining whether the CP line is open-circuited or short-circuited (operation S207), and an operation of storing a fault diagnosis result of the CP line (operation S208), and proceed to operation S216 to terminate the CP line fault diagnosis.

The method may perform an operation of disconnecting the charging connector (operation S209) and an operation of determining whether or not a CP fault diagnosis result exists (operation S210). In a case where it is determined that the CP fault diagnosis result does not exist, the method may proceed to operation S216 to terminate the CP line fault diagnosis for the CP line.

In a case where it is determined that the CP fault diagnosis result exists, the method may perform an operation of turning on the switch S4 (operation S211), an operation of obtaining the first voltage V₁, the second voltage V₂, and the third voltage V₃ (operation S212), an operation of determining whether a portion of the CP line between the charger 30 and the inlet 20 or a portion of the CP line between the inlet 20 and the first node has failed (operation S213), an operation of determining a specific fault type (operation S214), and an operation of determining whether or not the final fault type may be confirmed (operation S215). In a case where it is determined that the final fault type may not be confirmed, the method may proceed to operation 216 to terminate the CP line fault diagnosis.

In a case where it is determined that the final fault type may be confirmed, the method may perform an operation of storing a diagnostic trouble code (DTC) (operation S217).

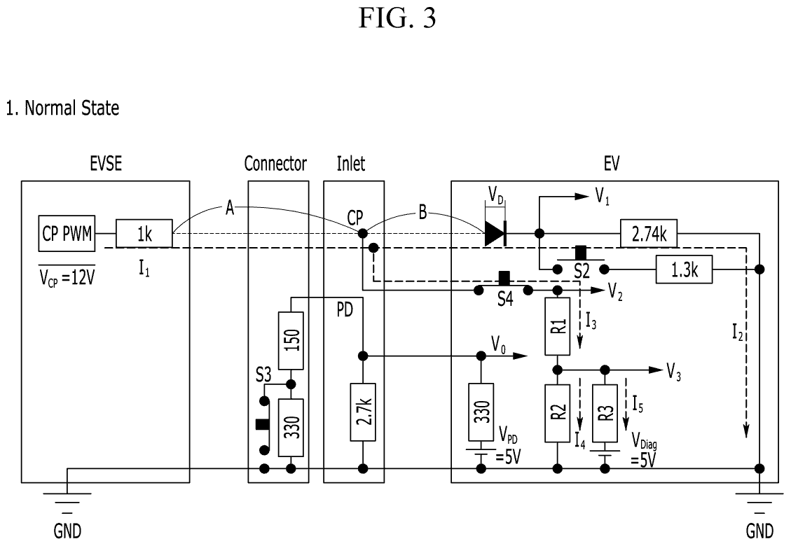

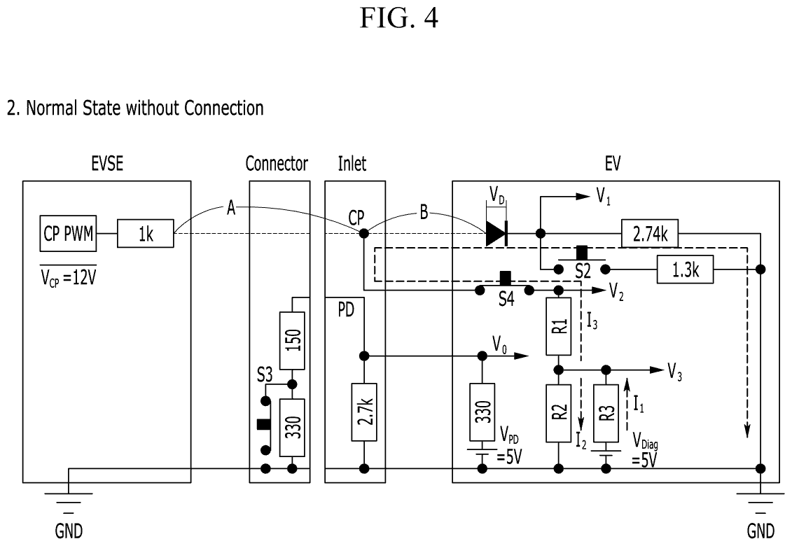

FIGS. 3 and 4 are diagrams illustrating the fault diagnosis device of FIG. 1 when no fault occurs.

Referring to FIG. 3, when the connector 40 of the charger 30 is connected to the inlet 20, the first voltage V₁, the second voltage V₂, and the third voltage V₃ may be as follows:

$${V}_{1} = 2.74 {kI}_{2} \qquad ( first voltage )$$

$${V}_{2} = 2.74 {kI}_{2} + {V}_{D} \qquad ( second voltage )$$

$$( third voltage )$$

$${V}_{3} = \frac{{R}_{2} {R}_{3} ( 2 \text{.74} k {V}_{CP} + 1 k {V}_{D} ) + {V}_{Diag} {R}_{2} ( 2 \text{.74} {kR}_{1} + 1 {kR}_{1} + 2.74 k \cdot 1 k )}{{R}_{2} {R}_{3} ( 2.74 k + 1 k ) + ( {R}_{2} + {R}_{3} ) ( 2 \text{.74} {kR}_{1} + 1 {kR}_{1} + 2.74 k \cdot 1 k )}$$

Referring to FIG. 4, when the connector 40 of the charger 30 is not connected to the inlet 20, the first voltage V₁, the second voltage V₂, and the third voltage V₃ may be as follows:

$${V}_{1} = \frac{2.74 k ( {V}_{3} - {V}_{D} )}{2.74 k + {R}_{1}} \qquad ( first voltage )$$

$${V}_{2} = \frac{2.74 k ( {V}_{3} - {V}_{D} )}{2.74 k + {R}_{1}} + {V}_{D} \qquad ( second voltage )$$

$${V}_{3} = \frac{{V}_{D} {R}_{2} {R}_{3} + {V}_{Diag} {R}_{2} ( 2.74 k + {R}_{1} )}{( {R}_{2} + {R}_{3} ) ( 2.74 k + {R}_{1} ) + {R}_{2} {R}_{3}} \qquad ( third voltage )$$

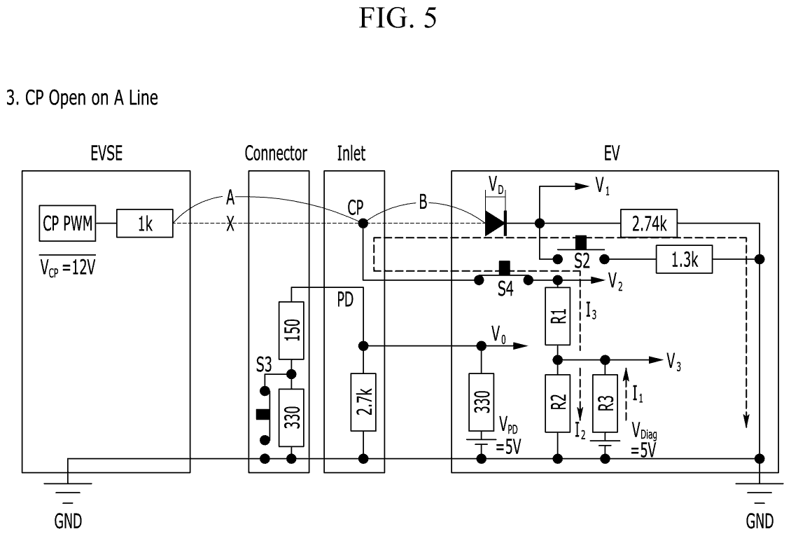

FIGS. 5 to 17 are diagrams illustrating the fault diagnosis device of FIG. 1 when a fault occurs.

The fault diagnosis device 100 may include a processor. The processor may measure the first voltage V₁ of the first node, the second voltage V₂ of the second node, and the third voltage V₃ of the third node of the fault diagnosis device 100 to diagnose a fault on the CP line. Hereinafter, the first resistor may be a resistor having one end connected to the second node and the other end connected to the third node in the fault diagnosis device 100, the second resistor may be a resistor having one end connected to the third node and the other end connected to the second terminal node in the fault diagnosis device 100, and a third resistor may be a resistor having one end connected to the third node and the other end connected to the fault diagnosis power supply V_{Diag}. Further, a fourth resistor may be a resistor connected to the cathode of the diode 11 indicated as 2.74 k in the vehicle 10, for example.

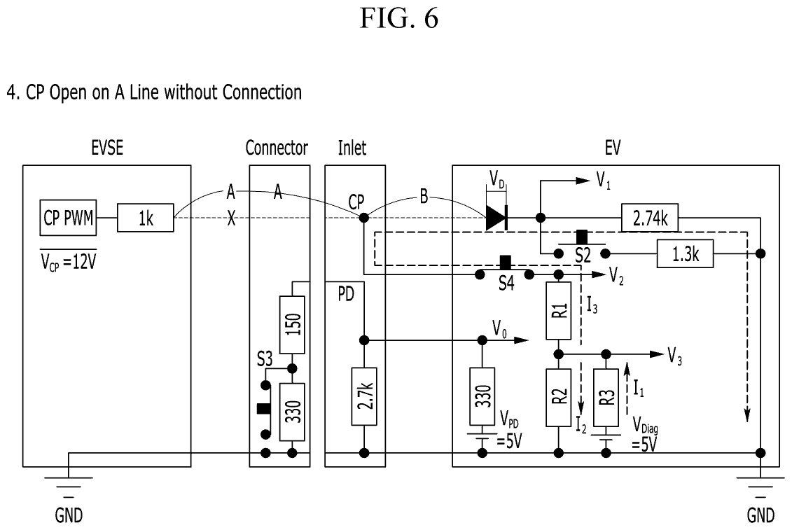

Referring to FIGS. 5 and 6 together, the processor may diagnose that the CP line is open-circuited between the charger 30 and the inlet 20 in a case where the first voltage V₁, the second voltage V₂, and the third voltage V₃ are measured according to Equation 1-1, Equation 1-2, and Equation 1-3.

$${V}_{1} = \frac{{R}_{11} ( {V}_{3} - {V}_{D} )}{{R}_{11} + {R}_{1}} \qquad ( Equation 1 - 1 )$$

$${V}_{2} = \frac{{R}_{11} ( {V}_{3} - {V}_{D} )}{{R}_{11} + {R}_{1}} + {V}_{D} \qquad ( Equation 1 - 2 )$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 1 - 3 )$$

Here, R₁ may represent a first resistance, R₂ may represent a second resistance, R₃ may represent a third resistance, R₁₁ may represent a fourth resistance, V₁ may represent the first voltage, V₂ may represent the second voltage, V₃ may represent the third voltage, V_{Diag} may represent a voltage of the fault diagnosis power supply, and V_{D} may represent a conduction voltage of the diode.

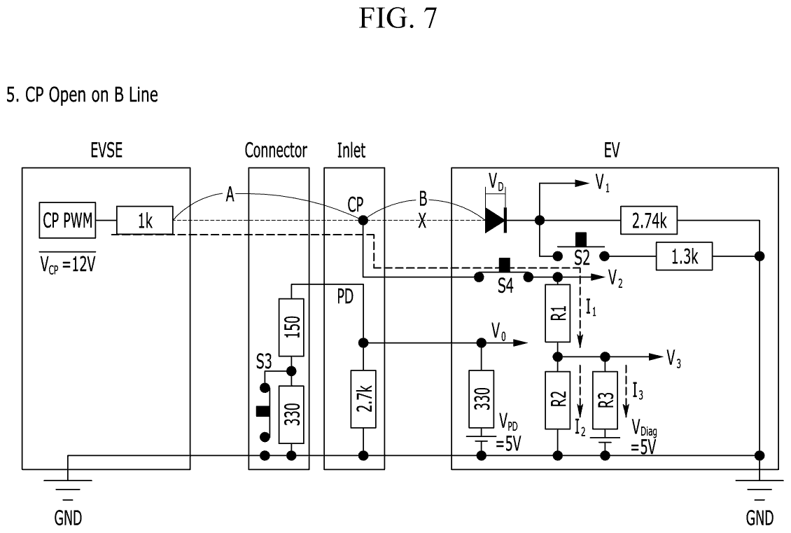

Referring to FIG. 7, the processor may diagnose that the connector 40 of the charger 30 is connected to the inlet 20, and the CP line is open-circuited between the inlet 20 and the first node in a case where the first voltage V₁, the second voltage V₂, and the third voltage V₃ are measured according to Equation 2-1, Equation 2-2, and Equation 2-3.

$${V}_{1} = 0 \qquad ( Equation 2 - 1 )$$

$${V}_{2} = {V}_{CP} - \frac{{R}_{31} ( {V}_{CP} - {V}_{3} )}{{R}_{1} + {R}_{31}} \qquad ( Equation 2 - 2 )$$

$${V}_{3} = \frac{{V}_{CP} {R}_{2} {R}_{3} + {V}_{Diag} ( {R}_{1} + {R}_{31} ) {R}_{2}}{( {R}_{1} + {R}_{31} ) {R}_{2} + ( {R}_{1} + {R}_{31} ) {R}_{3} + {R}_{2} {R}_{3}} \qquad ( Equation 2 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, V_{Diag} may represent the voltage of the fault diagnosis power supply, V_{CP} may represent a CP voltage provided by the charger 30, and R₃₁ may represent a resistance of the resistor connected to an output terminal of the CP PWM generation circuit 31 in the charger 30.

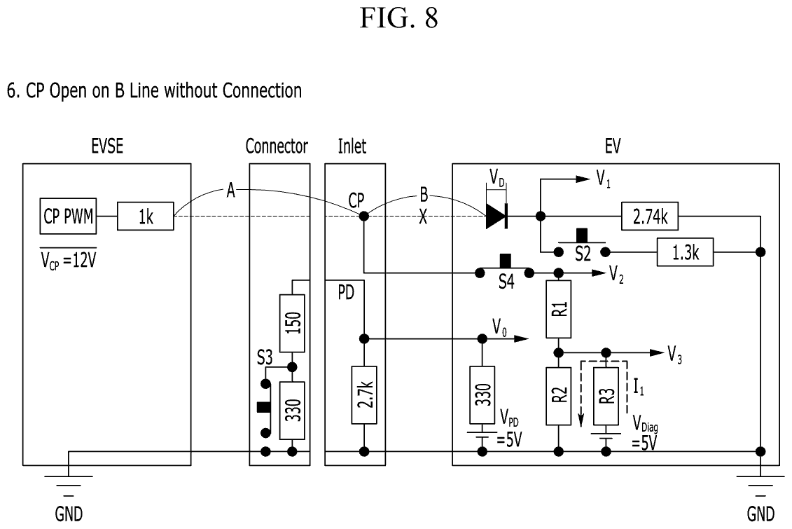

Referring to FIG. 8, the processor may diagnose that the connector 40 of the charger 30 is not connected to the inlet 20, and the CP line is open-circuited between the inlet 20 and the first node in a case where the first voltage V₁, the second voltage V₂, and the third voltage V₃ are measured according to Equation 3-1, Equation 3-2, and Equation 3-3.

$${V}_{1} = 0 \qquad ( Equation 3 - 1 )$$

$${V}_{2} = {V}_{3} \qquad ( Equation 3 - 2 )$$

$${V}_{3} = {V}_{Diag} \frac{{R}_{2}}{{R}_{2} + {R}_{3}} \qquad ( Equation 3 - 3 )$$

Here, R₂ may represent the second resistance, R₃ may represent the third resistance, V₁ may represent the first voltage, V₂ may represent the second voltage, V₃ may represent the third voltage, and V_{Diag} may represent the voltage of the fault diagnosis power supply.

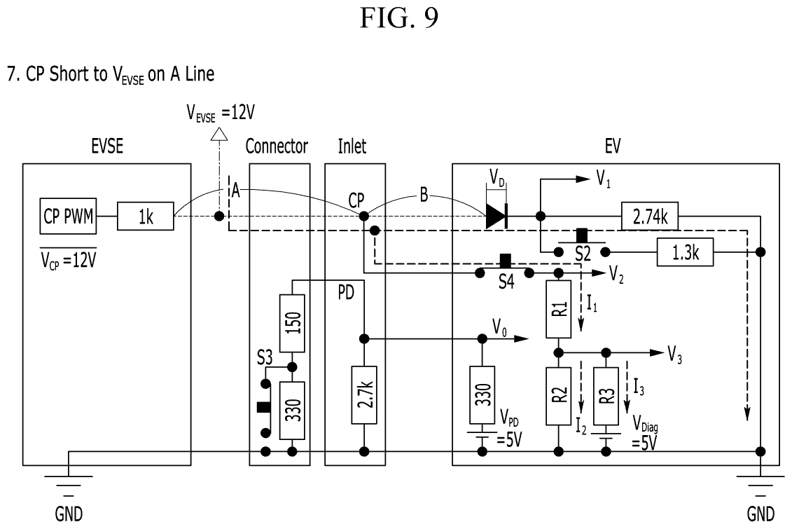

Referring to FIG. 9, the processor may diagnose that the connector 40 of the charger 30 is connected to the inlet 20, and the CP line is short-circuited to a charger power supply voltage V_{EVSE} between the charger 30 and the inlet 20 in a case where the first voltage V₁, the second voltage V₂, and the third voltage V₃ are measured according to Equation 4-1, Equation 4-2, and Equation 4-3.

$${V}_{1} = {V}_{EVSE} - {V}_{D} \qquad ( Equation 4 - 1 )$$

$${V}_{2} = {V}_{EVSE} \qquad ( Equation 4 - 2 )$$

$${V}_{3} = \frac{{V}_{EVSE} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad ( Equation 4 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, V_{Diag} may represent the voltage of the fault diagnosis power supply, and V_{EVSE} may represent the charger power supply voltage.

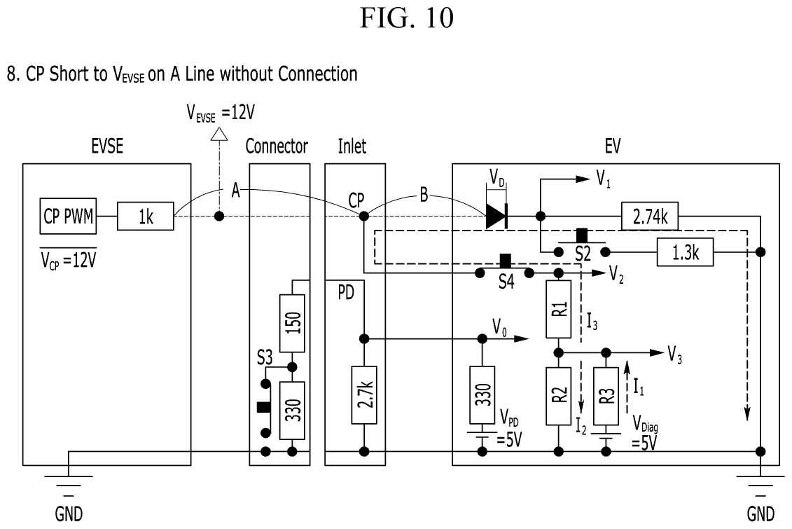

Referring to FIG. 10, the processor may diagnose that the connector 40 of the charger 30 is not connected to the inlet 20, and the CP line is short-circuited to the charger power supply voltage V_{EVSE} between the charger 30 and the inlet 20 in a case where the first voltage V₁, the second voltage V₂, and the third voltage V₃ are measured according to Equation 5-1, Equation 5-2, and Equation 5-3.

$${V}_{1} = \frac{{R}_{11} ( {V}_{3} - {V}_{D} )}{{R}_{11} + {R}_{1}} \qquad ( Equation 5 - 1 )$$

$${V}_{2} = \frac{{R}_{11} ( {V}_{3} - {V}_{D} )}{{R}_{11} + {R}_{1}} + {V}_{D} \qquad ( Equation 5 - 2 )$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 5 - 3 )$$

Here, R₁ may represent the first resistance, R₂ may represent the second resistance, R₃ may represent the third resistance, R₁₁ may represent the fourth resistance, V₁ may represent the first voltage, V₂ may represent the second voltage, V₃ may represent the third voltage, V_{Diag} may represent the voltage of the fault diagnosis power supply, and V_{D} may represent the conduction voltage of the diode.

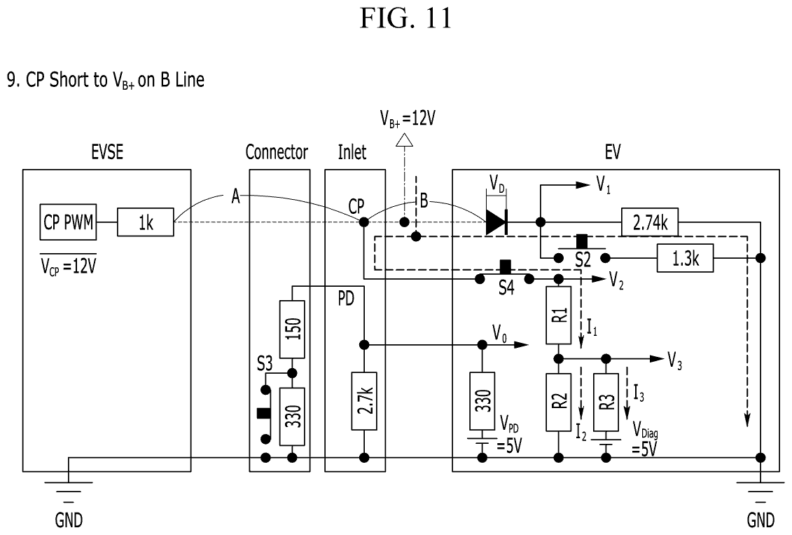

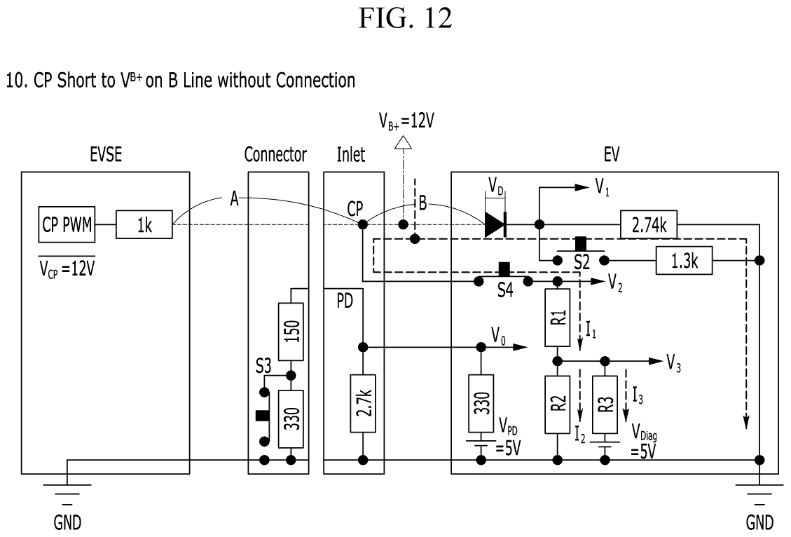

Referring to FIGS. 11 and 12 together, the processor may diagnose that the CP line is short-circuited to a vehicle power supply voltage V_{B+} between the inlet 20 and the first node in a case where the first voltage V₁, the second voltage V₂, and the third voltage V₃ are measured according to Equation 6-1, Equation 6-2, and Equation 6-3.

$${V}_{1} = {V}_{B +} - {V}_{D} \qquad ( Equation 6 - 1 )$$

$${V}_{2} = {V}_{B +} \qquad ( Equation 6 - 2 )$$

$${V}_{3} = \frac{{V}_{B +} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad ( Equation 6 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, V_{Diag} may represent the voltage of the fault diagnosis power supply, V_{B+} may represent the vehicle power supply voltage, and V_{D} may represent the conduction voltage of the diode.

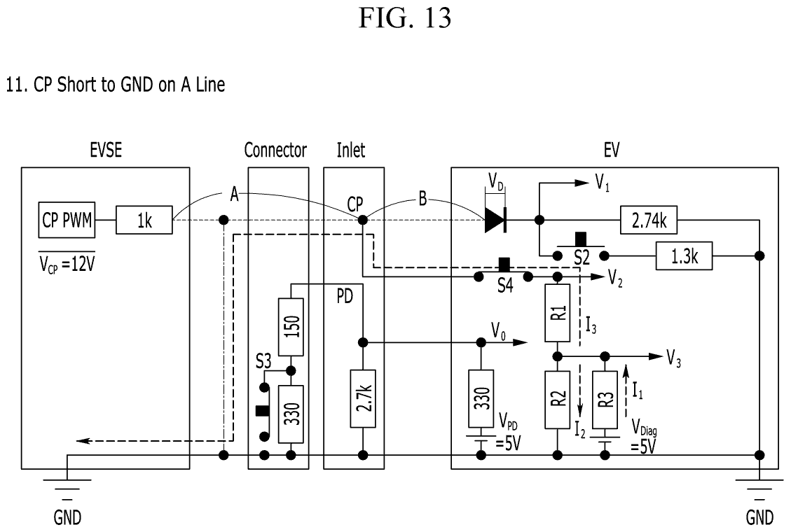

Referring to FIG. 13, the processor may diagnose that the connector 40 of the charger 30 is connected to the inlet 20, and the CP line is short-circuited to the ground between the charger 30 and the inlet 20 in a case where the first voltage V₁, the second voltage V₂, and the third voltage V₃ are measured according to Equation 7-1, Equation 7-2, and Equation 7-3.

$${V}_{1} = 0 \qquad ( Equation 7 - 1 )$$

$${V}_{2} = 0 \qquad ( Equation 7 - 2 )$$

$${V}_{3} = \frac{{V}_{Diag} {R}_{1} {R}_{2}}{{R}_{1} {R}_{2} + {R}_{1} {R}_{3} + {R}_{2} {R}_{3}} \qquad ( Equation 7 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, and V_{Diag} may represent the voltage of the fault diagnosis power supply.

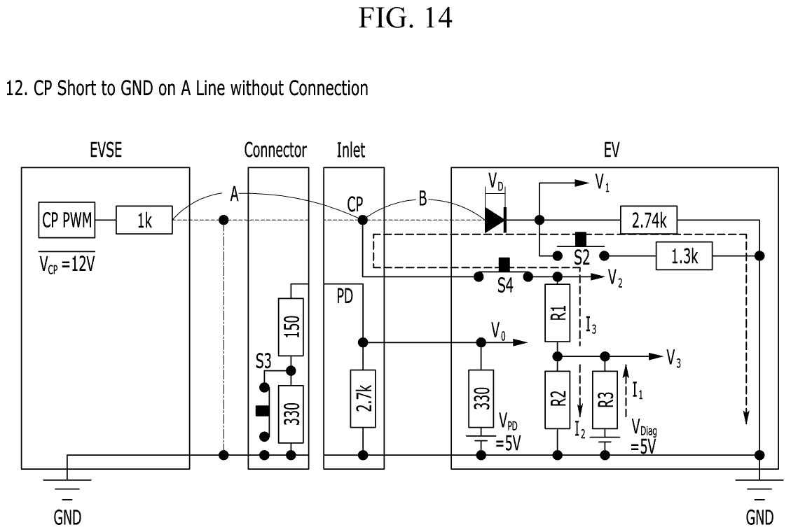

Referring to FIG. 14, the processor may diagnose that the connector 40 of the charger 30 is not connected to the inlet 20, and the CP line is short-circuited to the ground between the charger 30 and the inlet 20 in a case where the first voltage V₁, the second voltage V₂, and the third voltage V₃ are measured according to Equation 8-1, Equation 8-2, and Equation 8-3.

$${V}_{1} = \frac{{R}_{11} ( {V}_{3} - {V}_{D} )}{{R}_{11} + {R}_{1}} \qquad ( Equation 8 - 1 )$$

$${V}_{2} = \frac{{R}_{11} ( {V}_{3} - {V}_{D} )}{{R}_{11} + {R}_{1}} + {V}_{D} \qquad ( Equation 8 - 2 )$$

$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 8 - 3 )$$

Here, R₁ may represent the first resistance, R₂ may represent the second resistance, R₃ may represent the third resistance, R₁₁ may represent the fourth resistance, V₁ may represent the first voltage, V₂ may represent the second voltage, V₃ may represent the third voltage, V_{Diag} may represent the voltage of the fault diagnosis power supply, and V_{D} may represent the conduction voltage of the diode.

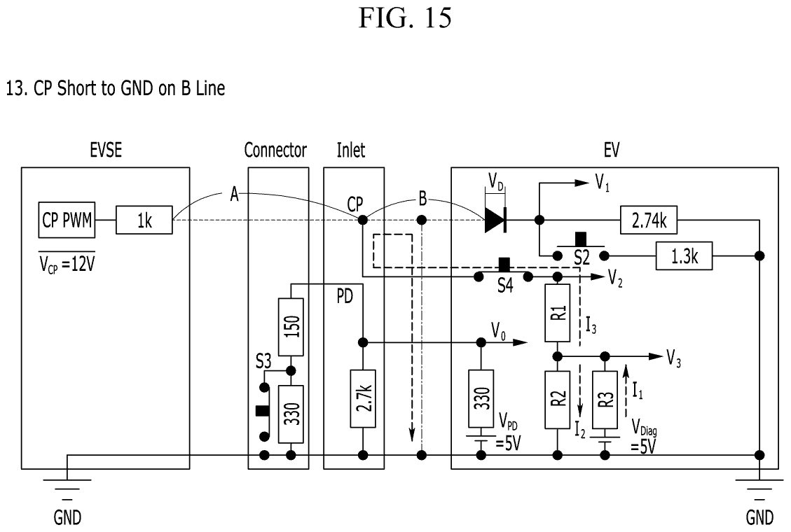

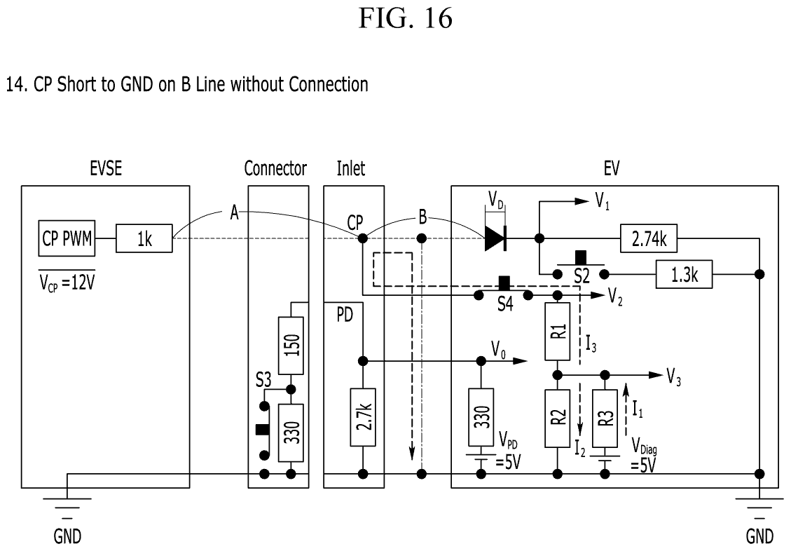

Referring to FIGS. 15 and 16 together, the processor may diagnose that the CP line is short-circuited between the inlet 20 and the first node in a case where the first voltage V₁, the second voltage V₂, and the third voltage V₃ are measured according to Equation 9-1, Equation 9-2, and Equation 9-3.

$${V}_{1} = 0 \qquad ( Equation 9 - 1 )$$

$${V}_{2} = 0 \qquad ( Equation 9 - 2 )$$

$${V}_{3} = \frac{{V}_{Diag} {R}_{1} {R}_{2}}{{R}_{1} {R}_{2} + {R}_{1} {R}_{3} + {R}_{2} {R}_{3}} \qquad ( Equation 9 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, and V_{Diag} may represent the voltage of the fault diagnosis power supply.

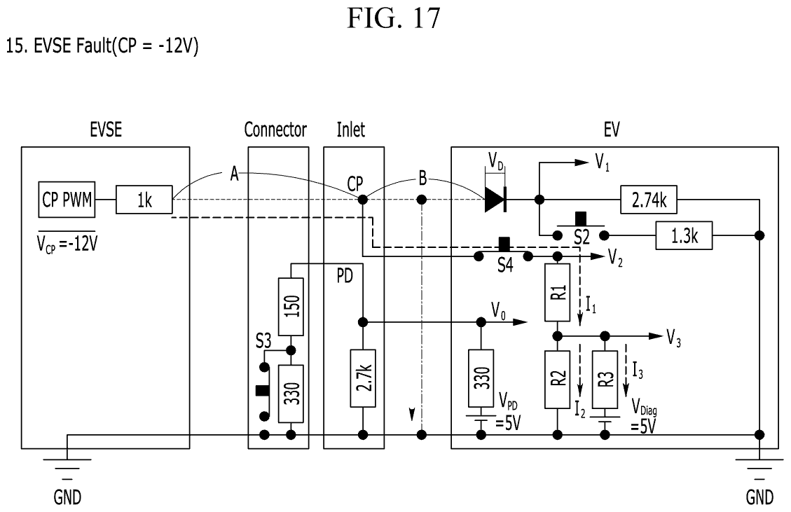

Referring to FIG. 17, the processor may diagnose that an internal fault of the charger 30 has occurred in a case where the first voltage V₁, the second voltage V₂, and the third voltage V₃ are measured according to Equation 10-1, Equation 10-2, and Equation 10-3. In a case where the internal fault of the charger 30 has occurred, the CP voltage is output as −12 V. Therefore, the internal fault of the charger 30 may be distinguished from a fault caused by the open circuit or short circuit of the CP line.

$${V}_{1} = 0 \qquad ( Equation 10 - 1 )$$

$${V}_{2} = {V}_{CP} - \frac{{R}_{31} ( {V}_{CP} - {V}_{3} )}{{R}_{1} + {R}_{31}} \qquad ( Equation 10 - 2 )$$

$${V}_{3} = \frac{{V}_{CP} {R}_{2} {R}_{3} + {V}_{Diag} ( {R}_{1} + {R}_{31} ) {R}_{2}}{( {R}_{1} + {R}_{31} ) {R}_{2} + ( {R}_{1} + {R}_{31} ) {R}_{3} + {R}_{2} {R}_{3}} \qquad ( Equation 10 - 3 )$$

Here, R₁ may represent the first resistance, R₂ may represent the second resistance, R₃ may represent the third resistance, V₁ may represent the first voltage, V₂ may represent the second voltage, V₃ may represent the third voltage, V_{Diag} may represent the voltage of the fault diagnosis power supply, V_{CP} may represent the CP voltage provided by the charger 30, and R₃₁ may represent the resistance of the resistor connected to the output terminal of the CP PWM generation circuit 31 in the charger 30.

The fault on the CP line may be diagnosed by loading data in which result values calculated from predetermined equations for each fault type are stored into the memory and comparing calculated result values read from the memory and the result values of the first voltage V₁, the second voltage V₂, and the third voltage V₃ measured as in FIGS. 5 to 17.

According to example embodiments, when electric vehicle charging is stopped, a fault on the CP line may be accurately diagnosed by the vehicle itself, and when charging is not possible due to a fault, the specific fault type may be analyzed and the electric vehicle charging system may be stably stopped, thereby improving the overall reliability and safety of the electric vehicle charging system.

Although example embodiment of the present disclosure has been described in detail hereinabove, the scopes of the present disclosure are not necessarily limited thereto. That is, several modifications and alterations made by a person of ordinary skill in the art to which the present disclosure pertains using concepts of the present disclosure as defined in the claims falling within the scopes of the present disclosure.

What is claimed is:

1. A fault diagnosis device comprising:
a first terminal node configured to receive a control pilot (CP) signal from a connector of a charger through an inlet and configured to be connected to an anode of a diode;
a first node connected to a cathode of the diode;
a second node selectively connected to the first terminal node by a switch;
a third node connected to the second node through a first resistor;
a second terminal node connected to the third node through a second resistor; and
a processor configured to measure a first voltage of the first node, a second voltage of the second node, and a third voltage of the third node to diagnose a fault on a CP line.

2. The device of claim 1, wherein the second terminal node is connected to the third node through a third resistor and a fault diagnosis power supply.

3. The device of claim 2, wherein
the second terminal node is connected to the first node through a fourth resistor.

4. The device of claim 3, wherein
the processor is configured to diagnose that the CP line is open-circuited between the charger and the inlet in a case where the first voltage, the second voltage, and the third voltage are measured according to Equation 1-1, Equation 1-2, and Equation 1-3:
$${V}_{1} = \frac{{R}_{11} ( {V}_{3} - {V}_{D} )}{{R}_{11} + {R}_{1}} \qquad ( Equation 1 - 1 )$$
$${V}_{2} = \frac{{R}_{11} ( {V}_{3} - {V}_{D} )}{{R}_{11} + {R}_{1}} + {V}_{D} \qquad ( Equation 1 - 2 )$$
$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 1 - 3 )$$
wherein R1 represents a first resistance of the first resistor, R2 represents a second resistance of the second resistor, R3 represents a third resistance of the third resistor, R11 represents a fourth resistance of the fourth resistor, V1 represents the first voltage, V2 represents the second voltage, V3 represents the third voltage, V_{Diag} represents a diagnostic voltage of the fault diagnosis power supply, and V_{D} represents a conduction voltage of the diode.

5. The device of claim 3, wherein the processor is configured to diagnose that the connector of the charger is connected to the inlet, and the CP line is open-circuited between the inlet and the first node, in a case where the first voltage, the second voltage, and the third voltage are measured according to Equation 2-1, Equation 2-2, and Equation 2-3:
$${V}_{1} = 0 \qquad ( Equation 2 - 1 )$$
$${V}_{2} = {V}_{CP} - \frac{{R}_{31} ( {V}_{CP} - {V}_{3} )}{{R}_{1} + {R}_{31}} \qquad ( Equation 2 - 2 )$$
$$V\_ 3 = ( V\_CP R\_ 2 R\_ 3 + V\_Diag ( R \_ 1 + R\_ 31 ) R\_ 2 ) / ( ( R \_ 1 + R\_ 31 ) R\_ 2 + ( R {1}_{} + {R}_{31} ) R\_ 3 + R\_ 2 R\_ 3 ) \qquad ( Equation 2 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, V_{Diag} represent a diagnostic voltage of the fault diagnosis power supply, V_{CP} represents a CP voltage provided by the charger, and R31 represents a fifth resistance of a fifth resistor connected to an output terminal of a CP pulse width modulation generation circuit in the charger.

6. The device of claim 3, wherein the processor is configured to diagnose that the connector of the charger is not connected to the inlet, and the CP line is open-circuited between the inlet and the first node, in a case where the first voltage, the second voltage, and the third voltage are measured according to Equation 3-1, Equation 3-2, and Equation 3-3:
$${V}_{1} = 0 \qquad ( Equation 3 - 1 )$$
$${V}_{2} = {V}_{3} \qquad ( Equation 3 - 2 )$$
$${V}_{3} = {V}_{Diag} \frac{{R}_{2}}{{R}_{2} + {R}_{3}} \qquad ( Equation 3 - 3 )$$
wherein R2 represents a second resistance of the second resistor, R3 represents a third resistance of the third resistor, V1 represents the first voltage, V2 represents the second voltage, V3 represents the third voltage, and V_{Diag} represents a diagnostic voltage of the fault diagnosis power supply.

7. The device of claim 3, wherein the processor is configured to diagnose that the connector of the charger is connected to the inlet, and the CP line is short-circuited between the charger and the inlet, in a case where the first voltage, the second voltage, and the third voltage are measured according to Equation 4-1, Equation 4-2, and Equation 4-3:
$${V}_{1} = {V}_{EVSE} - {V}_{D} \qquad ( Equation 4 - 1 )$$
$${V}_{2} = {V}_{EVSE} \qquad ( Equation 4 - 2 )$$
$${V}_{3} = \frac{{V}_{EVSE} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad ( Equation 4 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, V_{Diag} represents a diagnostic voltage of the fault diagnosis power supply, and V_{EVSE} represents a charger power supply voltage.

8. The device of claim 3, wherein the processor is configured to diagnose that the connector of the charger is not connected to the inlet, and the CP line is short-circuited to a charger power supply voltage between the charger and the inlet, in a case where the first voltage, the second voltage, and the third voltage are measured according to Equation 5-1, Equation 5-2, and Equation 5-3:
$${V}_{1} = \frac{{R}_{11} ( {V}_{3} - {V}_{D} )}{{R}_{11} + {R}_{1}} \qquad ( Equation 5 - 1 )$$
$${V}_{2} = \frac{{R}_{11} ( {V}_{3} - {V}_{D} )}{{R}_{11} + {R}_{1}} + {V}_{D} \qquad ( Equation 5 - 2 )$$
$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 5 - 3 )$$
wherein R1 represents a first resistance of the first resistor, R2 represents a second resistance of the second resistor, R3 represents a third resistance of the third resistor, R11 represents a fourth resistance of the fourth resistor, V1 represents the first voltage, V2 represents the second voltage, V3 represents the third voltage, V_{Diag} represents a diagnostic voltage of the fault diagnosis power supply, and V_{D} represents a conduction voltage of the diode.

9. The device of claim 3, wherein the processor is configured to diagnose that the CP line is short-circuited to a vehicle power supply voltage between the inlet and the first node in a case where the first voltage, the second voltage, and the third voltage are measured according to Equation 6-1, Equation 6-2, and Equation 6-3:
$${V}_{1} = {V}_{B +} - {V}_{D} \qquad ( Equation 6 - 1 )$$
$${V}_{2} = {V}_{B +} \qquad ( Equation 6 - 2 )$$
$${V}_{3} = \frac{{V}_{B +} {R}_{2} {R}_{3} + {V}_{Diag} {R}_{1} {R}_{2}}{{R}_{1} {R}_{2} + {R}_{1} {R}_{3} + {R}_{2} {R}_{3}} \qquad ( Equation 6 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, V_{Diag} represents a diagnostic voltage of the fault diagnosis power supply, V_{B+} represents the vehicle power supply voltage, and V_{D} represents a conduction voltage of the diode.

10. The device of claim 3, wherein the processor is configured to diagnose that the connector of the charger is connected to the inlet, and the CP line is short-circuited to a ground between the charger and the inlet, in a case where the first voltage, the second voltage, and the third voltage are measured according to Equation 7-1, Equation 7-2, and Equation 7-3:
$${V}_{1} = 0 \qquad ( Equation 7 - 1 )$$
$${V}_{2} = 0 \qquad ( Equation 7 - 2 )$$
$${V}_{3} = \frac{{V}_{Diag} {R}_{1} {R}_{2}}{{R}_{1} {R}_{2} + {R}_{1} {R}_{3} + {R}_{2} {R}_{3}} \qquad ( Equation 7 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, and V_{Diag} represents a diagnostic voltage of the fault diagnosis power supply.

11. The device of claim 3, wherein the processor is configured to diagnose that the connector of the charger is not connected to the inlet, and the CP line is short-circuited to a ground between the charger and the inlet, in a case where the first voltage, the second voltage, and the third voltage are measured according to Equation 8-1, Equation 8-2, and Equation 8-3:
$${V}_{1} = \frac{{R}_{11} ( {V}_{3} - {V}_{D} )}{{R}_{11} + {R}_{1}} \qquad ( Equation 8 - 1 )$$
$${V}_{2} = \frac{{R}_{11} ( {V}_{3} - {V}_{D} )}{{R}_{11} + {R}_{1}} + V\_D \qquad ( Equation 8 - 2 )$$
$${V}_{3} = \frac{{V}_{D} {R}_{2} {R}_{3} + {V}_{Diag} {R}_{2} ( {R}_{11} + {R}_{1} )}{( {R}_{2} + {R}_{3} ) ( {R}_{11} + {R}_{1} ) + {R}_{2} {R}_{3}} \qquad ( Equation 8 - 3 )$$
wherein R1 represents a first resistance of the first resistor, R2 represents a second resistance of the second resistor, R3 represents a third resistance of the third resistor, R11 represents a fourth resistance of the fourth resistor, V1 represents the first voltage, V2 represents the second voltage, V3 represents the third voltage, V_{Diag} represents a diagnostic voltage of the fault diagnosis power supply, and V_{D} represents a conduction voltage of the diode.

12. The device of claim 3, wherein the processor is configured to diagnose that the CP line is short-circuited to a ground between the inlet and the first node in a case where the first voltage, the second voltage, and the third voltage are measured according to Equation 9-1, Equation 9-2, and Equation 9-3:
$${V}_{1} = 0 \qquad ( Equation 9 - 1 )$$
$${V}_{2} = 0 \qquad ( Equation 9 - 2 )$$
$${V}_{3} = \frac{{V}_{Diag} {R}_{1} {R}_{2}}{{R}_{1} {R}_{2} + {R}_{1} {R}_{3} + {R}_{2} {R}_{3}} \qquad ( Equation 9 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, and V_{Diag} represents a diagnostic voltage of the fault diagnosis power supply.

13. The device of claim 3, wherein the processor is configured to diagnose that an internal fault of the charger has occurred in a case where the first voltage, the second voltage, and the third voltage are measured according to Equation 10-1, Equation 10-2, and Equation 10-3:
$${V}_{1} = 0 \qquad ( Equation 10 - 1 )$$
$${V}_{2} = {V}_{CP} - \frac{{R}_{31} ( {V}_{CP} - {V}_{3} )}{{R}_{1} + {R}_{31}} \qquad ( Equation 10 - 2 )$$
$$V\_ 3 = ( V\_CP {R}_{2} {R}_{3} + {V}_{Diag} ( R \_ 1 + R\_ 31 ) R\_ 2 ) / ( ( R \_ 1 + R\_ 31 ) R\_ 3 + R\_ 2 R\_ 3 ) \qquad ( Equation 10 - 3 )$$
wherein R1 represents a first resistance of the first resistor, R2 represents a second resistance of the second resistor, R3 represents a third resistance of the third resistor, V1 represents the first voltage, V2 represents the second voltage, V3 represents the third voltage, V_{Diag} represent a diagnostic voltage of the fault diagnosis power supply, V_{CP} represents a CP voltage provided by the charger, and R31 represents a fifth resistance of a fifth resistor connected to an output terminal of a CP pulse width modulation generation circuit in the charger.

14. A fault diagnosis method comprising:
turning on a switch;
measuring a first voltage of a first node connected to a cathode of a diode receiving a control pilot (CP) signal from a connector of a charger through an inlet;
measuring a second voltage of a second node selectively connected to a first terminal node connected to an anode of the diode by the switch;
measuring a third voltage of a third node connected to the second node through a first resistor;
loading data in which result values calculated from predetermined equations for each fault type are stored into a memory; and
diagnosing a fault on a CP line by comparing the calculated result values and measured result values of the measured first voltage, second voltage, and third voltage.

15. The method of claim 14, wherein
the turning on of the switch comprises
terminating charging; and
turning on the switch in response to the first voltage being in a predetermined range during vehicle charging.

16. The method of claim 14, further comprising:
identifying a first fault type in a first case where the connector of the charger is connected to the inlet;
identifying a second fault type in a second case where the connector of the charger is not connected to the inlet; and
confirming a final fault type by comparing the first fault type identified in the first case where the charger is connected to the inlet and the second fault type identified in the second case where the charger is not connected to the inlet.

17. A fault diagnosis device comprising:
a first terminal node configured to receive a control pilot (CP) signal from a connector of a charger through an inlet and configured to be connected to an anode of a diode;
a first node connected to a cathode of the diode;
a second node selectively connected to the first terminal node by a switch;
a third node connected to the second node through a first resistor;
a second terminal node connected to the third node through a second resistor; and
a processor configured to measure a first voltage of the first node, a second voltage of the second node, and a third voltage of the third node to diagnose a fault on a CP line by loading data in which result values calculated from predetermined equations for each fault type are stored into a memory and diagnosing the fault on the CP line by comparing the calculated result values and measured result values of the measured first voltage, second voltage, and third voltage.

18. The device of claim 17, wherein the processor is further configured to:
identify a first fault type in a first case where the connector of the charger is connected to the inlet;
identify a second fault type in a second case where the connector of the charger is not connected to the inlet; and
confirm a final fault type by comparing the first fault type identified in the first case where the charger is connected to the inlet and the second fault type identified in the second case where the charger is not connected to the inlet.

19. The device of claim 17, wherein the second terminal node is connected to the third node through a third resistor and a fault diagnosis power supply.

20. The device of claim 19, wherein the second terminal node is connected to the first node through a fourth resistor.
